(19) United States
(12) Patent Application Publication
(10) Pub. No.: US 2012/0032328 A1
(43) Pub. Date: Feb. 9, 2012

(54) Package structure with underfilling material and packaging method thereof

(75) Inventors: Yu-Yu Lin, Hsinchu City (TW); Chung-Kai Wang, Taipei County (TW); Li-Hua Lin, Hsinchu City (TW)

(73) Assignee: Global Unichip Corporation, Hsinchu City (TW)

(21) Appl. No.: 12/923,462

(22) Filed: Sep. 23, 2010

(30) Foreign Application Priority Data
Aug. 4, 2010 (TW) 099125850

(51) Int. Cl. H01L 23/48; H01L 21/56

(52) U.S. Cl. 257/738; 438/108; 257/E21.503; 257/E21.021; 257/778

(57) ABSTRACT

A method for packaging semiconductor device is provided, which comprises: providing a carrier substrate having a top surface and a back surface, a circuit arrangement on the top surface of the carrier substrate, and a through hole is disposed near the center of the carrier substrate and is formed passed through the carrier substrate; providing a chip having an active surface and a back surface, a plurality of pads is disposed on the periphery of the active surface and a plurality of connecting elements is disposed thereon; the active surface of chip is flipped and bonded on the circuit arrangement on the top surface of the carrier substrate, and the plurality of connecting elements is not covering the through hole; filling the underfilling material to encapsulate between the plurality of connecting elements and the top surface of the carrier substrate and to fill with the through hole; and performing a suction process to remove the air within the underfilling material between the plurality of connecting elements on the chip and the top surface of the carrier substrate, such that the underfilling material can completely encapsulate between the plurality of connecting elements on the chip and the top surface of the carrier surface.

### BACKGROUND OF THE INVENTION

1. Field of the Invention

The present invention related to a semiconductor package structure, and more particularly to a semiconductor package structure with the underfilling material.

2. Description of the Prior Art

The Flip-chip technology and the bumped die technology are well known in the semiconductor package technology. The flip-chip technology or the bumped die technology is a technology for a semiconductor chip having bumps on the bond pads that is formed on the active surface of the circuit board or on front side thereof, the bumps provide electrical and mechanical connection for the circuit board and other elements. The flip-chip technology is applied to invert the active surface and the back surface of the chip and bond the chip to a semiconductor substrate by means of the bumps. Several materials are typically used to form the bumps on the die, such as conductive polymers, solder and the like. The die with solder balls is often referred to as a Ball Grid Array (BGA). Typically, the solder bumps are reflowed to form a solder joint between the flip chip and the substrate, forming both electrical and mechanical connections between the flip chip and the substrate. Moreover, because the bumps are formed on the die, if the die is formed on the substrate by flip-chip technology, a gap exists between the substrate and the flip chip.

However, because the flip chip and the substrate typically have different coefficients of thermal expansion (CTE), during the flip chip and the substrate operate at different temperatures; different mechanical loading and stresses are happened. Because of these differences, shear stress develops in the joints formed by the bumps between the flip chip and substrate. Therefore, the bumps must be sufficiently robust to withstand such stressful condition to maintain the integrity of the joint between the flip chip and the substrate. To enhance the joint integrity formed by the bumps located between the flip chip and the substrate, and the underfilling material includes a suitable insulating polymer that is introduced in the gap between the flip chip and the substrate. The underfilling material serves to equalize stress placed on the flip chip, and to protect the bump connections located between the flip chip and the substrate.

In practice, the underfilling material is typically dispensed into the periphery around the chip by injection of the underfilling material flowing, usually by capillary action, to fill between the flip chip and the substrate. Unfortunately, the void is generated within the underfilling material between the flip chip and the substrate to reduce the yield of the product when the underfilling material with the air therein to fill between the flip chip and the substrate that through a hole in the substrate beneath the chip or the short circuit would be generated when the bump is melted under the higher operating temperature.

### SUMMARY OF THE INVENTION

According to above problems, the primary objective of the present invention is to provide a semiconductor package device which having at least one through hole therein. After the underfilling process is finished, a suction process can be performed to remove the air within the underfilling material between the substrate and the flip chip, such that the underfilling material can encapsulate completely between the substrate and the flip chip.

Another primary objective of the present invention is to reduce the duration for filling the underfilling material and to cooperate with the suction process, such that the unity of the underfilling material between the substrate and the chip can be maintained and without any void within the underfilling material.

According to above objectives, the present invention provides a method for packaging semiconductor device, which includes: providing a carrier substrate having a top surface and a back surface, a circuit arrangement on the top surface of the carrier substrate, and at least one through hole is disposed near the center of the carrier substrate and is formed passed through the carrier substrate; providing a chip having an active surface and a back surface, a plurality of pads is disposed on the periphery of the active surface and a plurality of connecting elements is disposed thereon; attaching the chip on the top surface of the carrier substrate, the active surface of chip is flipped and bonded on the circuit arrangement on the top surface of the carrier substrate by means of the plurality of connecting elements, and the plurality of connecting elements is not covering the through hole; filling a underfilling material to encapsulate between the plurality of connecting elements and the top surface of the carrier substrate and to fill with the through hole; and performing a suction process to remove the air within the underfilling material between the plurality of connecting elements on the chip and the top surface of the carrier substrate, such that the underfilling material can completely encapsulate between the plurality of connecting elements on the chip and the top surface of the carrier surface.

According to the method for packaging the semiconductor device, the present invention also provides a semiconductor package device, which includes a carrier substrate having a top surface and a back surface, a circuit arrangement on the top surface and at least one through hole is disposed near the center of the carrier substrate and is formed passed through the carrier substrate; a chip having an active surface and a back surface, a plurality of pads is disposed on the periphery of the active surface and a plurality of connecting elements is disposed thereon, and the active surface of the chip is flipped and bonded on the circuit arrangement on the top surface of the chip by means of the plurality of connecting elements which is not covering on the though hole; and the underfilling material is encapsulated between the plurality of connecting elements on the chip and the top surface of the carrier substrate, and is filled with the through hole.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A is a vertical view of the carrier substrate that having a through hole therein according to the present invention disclosed herein;

FIG. 1B is a cross-sectional view of the carrier substrate that having a through hole therein according to the present invention disclosed herein;

FIG. 2 is a cross-sectional view of the chip that is flipped and bonded on the carrier substrate according to the present invention disclosed herein;

FIG. 3 is a cross-sectional view of some voids that exit in the underfilling material between the flip chip and the top surface of the carrier substrate when the underfilling material is filled into according to the present invention disclosed herein;

FIG. 4 is a cross-sectional view of a suction apparatus that is disposed under the through hole with the top surface of the carrier substrate to remove the voids within the underfilling material;

FIG. 5 is a cross-sectional view of the semiconductor package device with the underfilling material;

FIG. 6A is a vertical view of a carrier substrate that having a plurality of through holes therein according to the present invention disclosed herein;

FIG. 6B is a cross-sectional view of the carrier substrate that having a plurality of through holes therein according to the present invention disclosed herein;

FIG. 7 is a cross-sectional view of the chip that is flipped and bonded on the carrier substrate according to the present invention disclosed herein;

FIG. 8 is a cross-sectional view of some voids that exit in the underfilling material between the flip chip and the top surface of the carrier substrate when the underfilling material is filled into according to the present invention disclosed herein;

FIG. 9 is a cross-sectional view of a suction apparatus that is disposed under the plurality of through holes within the carrier substrate to remove the voids within the underfilling material; and

FIG. 10 is a cross-sectional view of semiconductor package device with the underfilling material.

### DESCRIPTION OF THE PREFERRED EMBODIMENT

The present invention will now be described more fully hereinafter with reference to the accompanying drawings, in which preferred embodiments are shown. The objective of the present invention is to provide a method for packaging semiconductor device. In the following, the well-known knowledge regarding the of the invention such as the formation of chip and the process for forming package structure would not be described in detail to prevent from arising unnecessary interpretations. However, this invention will be embodied in many different forms and should not be construed as limited to the embodiments set forth herein.

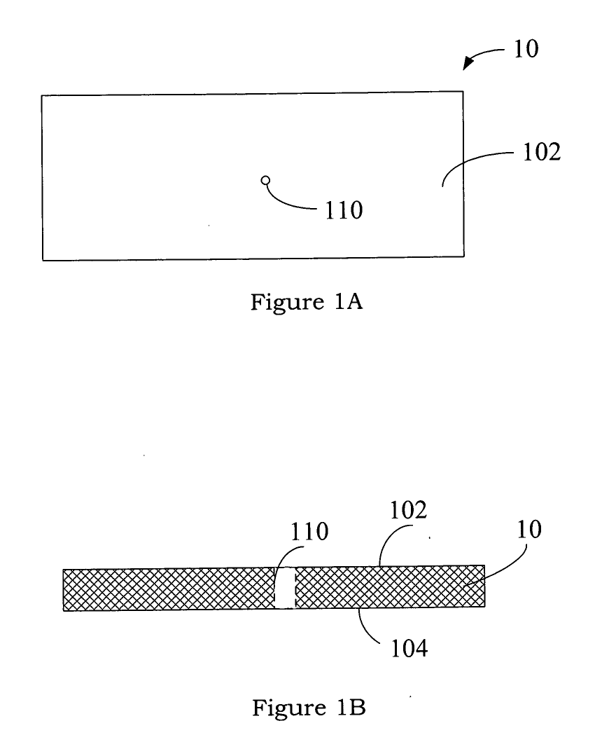

Please refer to FIG. 1A and FIG. 1B, shows the vertical view and the cross-sectional view of the carrier substrate that having at least one through hole therein, respectively. In FIG. 1A, a carrier substrate 10 is provided with a top surface 102 and a back surface (as shown in FIG. 1B), and a circuit arrangement (not shown) is disposed on the top surface 102 to electrically connect with the exterior electronic device (not shown). In addition, at least one through hole 110 is disposed near the center of the carrier substrate 10 and is formed to pass through the top surface 102 and the back surface 104 of the carrier substrate 10. Thus, the through hole 110 can be formed prior to the circuit arrangement that is designed on the carrier substrate 10, such that electrical connection between the carrier substrate 10 and other electronic device would not be affected by the through hole 110. In this embodiment, the through hole 110 within the carrier substrate 10 is formed by means of the mechanical punch. Moreover, the carrier substrate 10 can be the printed circuit board (PCB) or the flexible printed circuit board.

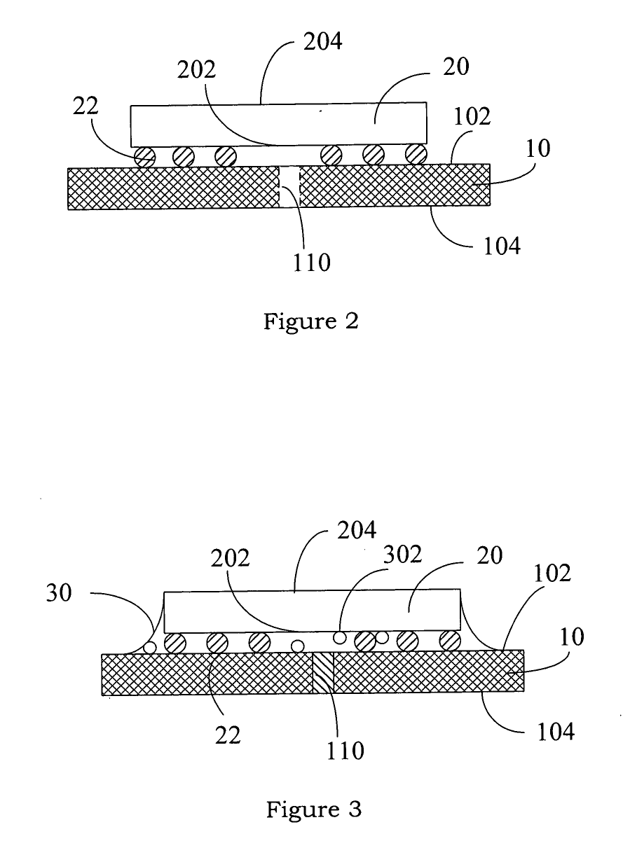

Then, please refer to FIG. 2, shows the cross-sectional view of the flip chip that is attached on the carrier substrate. In FIG. 2, a chip 20 is provided with an active surface 202 and a back surface 204, a plurality of pads (not shown) is disposed on the active surface 202, and a plurality of connecting elements 22 is disposed thereon. Next, the active surface 202 of the chip 20 is flipped and bonded on the circuit arrangement (not shown) on the top surface 102 of the carrier substrate 10, and the plurality of connecting elements 22 is electrically connected with the circuit arrangement on the carrier substrate 10. Herein, it is noted that the through hole 110 is first formed near the center of the carrier substrate 10 and the arrangement of the plurality of connecting elements 22 can be designed to dispose on the periphery of the active surface 202 of the chip 20, such that the plurality of connecting elements 22 would not be disposed or covered on the through hole 110, and the reliability of the semiconductor device would not be affected.

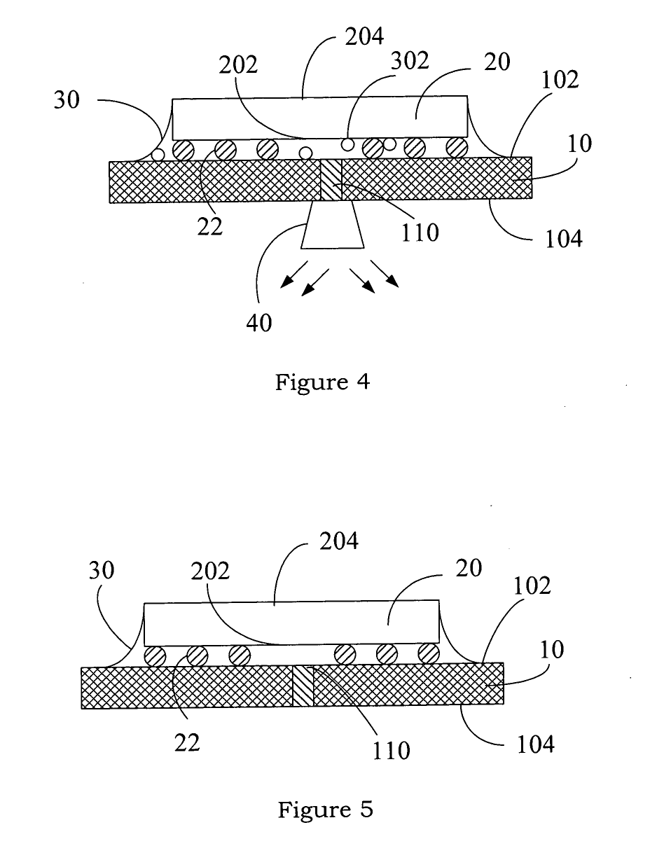

Then, please refer to FIG. 3, the underfilling material 30 is filled between the flip chip 20 and the carrier substrate 10, and is filled with the through hole 110 within the carrier substrate 10 to accomplish the package method of the flip chip 20. In the embodiment, the underfilling material 30 can increase the mechanical connection between the flip chip 20 and the carrier substrate 10, and the shearing stress is generated between the plurality of connecting elements 22, such as the solder ball and the flip chip 20 that can be dispersed. Herein, the material for the underfilling material 30 can be polymeric material, such as epoxy resin or acrylic resin, and the CTE (coefficient of the thermal expansion) of the underfilling material 30 is between about that of the flip chip 20 and that of the carrier substrate 10, so as to the shearing stress between the flip chip 20 and the carrier substrate 10 can be reduced. Unfortunately, some voids 302 is to be found within the underfilling material between the flip chip 20 and the top surface 102 of the carrier substrate 10 during the detecting process after the underfilling material process is accomplished. The reason for the generation of voids 302 is that the underfilling duration is increased to ensure the underfilling material 30 that can be completely encapsulated between the flip chip 20 and the top surface 102 of the carrier substrate 10. Therefore, when the underfilling material 30 is filled, the underfilling material 30 accompanies some air (not shown) to fill and some voids 302 would be generated between the flip chip 20 and the top surface 102 of the carrier substrate 10. However, the existence of the voids 302 will affect the reliability of the semiconductor device. Therefore, in order to improve the reliability of the semiconductor device, a suction apparatus 40 is disposed and covered under the through hole 110 within the back surface 104 of the carrier substrate 10 as shown in FIG. 4. The suction apparatus 40 is provided with a suction process to draw out the air within the underfilling material 30 to encapsulate completely between the flip chip 20 and the top surface 102 of the carrier substrate 10, and the underfilling material 30 without having any voids 302 therein so as to the reliability and the yield of the semiconductor device can be increased, as shown in FIG. 5. In the embodiment, the suction apparatus 40 can be a vacuum pump.

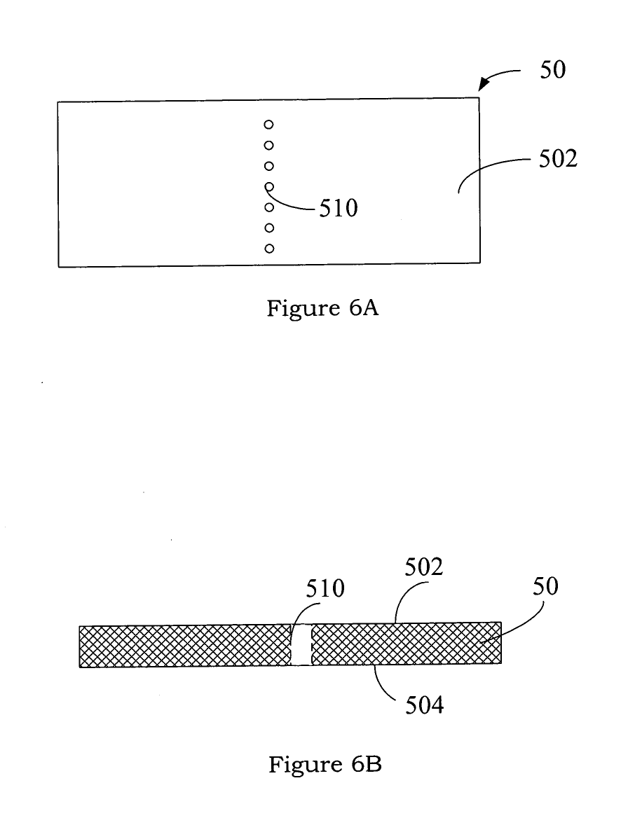

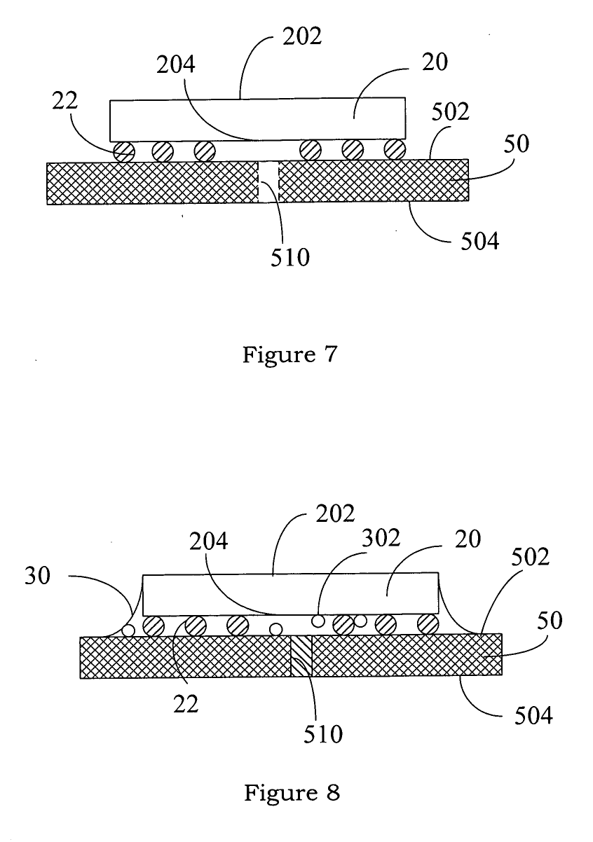

Next, please refer to FIG. 6A and FIG. 6B, shows the vertical view and the cross-sectional view of the carrier substrate having a plurality of through holes therein, respectively. In FIG. 6A, the carrier substrate 50 is provided with the top surface 502 and the back surface 504 (as shown in FIG. 6B). A circuit arrangement (not shown) is disposed on the top surface 502 of the carrier substrate 50 and is used to electrically connect with the exterior electronic device (not shown). In addition, a plurality of through holes 510 is disposed near the center of the carrier substrate 50 and is formed to pass through the top surface 502 and the back surface 504 of the carrier substrate 50. Therefore, the plurality of through holes 510 can be formed prior to the circuit arrangement which is disposed on the carrier substrate 50, and thus the electrical connection between the carrier substrate 50 and the exterior electronic device (not shown) would not be affected by the though holes 510. Otherwise, the arrangement for the though holes 510 can avoid the connecting elements on the active surface (not shown) of the chip, such that the through holes 510 would not be covered by the connecting elements (as shown in FIG. 7). In this embodiment, the through holes 510 are formed on the carrier substrate 50 by means of mechanical punch. In addition, herein, the carrier substrate 50 can be the printed circuit board (PCB) or the flexible printed circuit board.

Then, please refer to FIG. 7, shows the cross-sectional view of the flip chip that is disposed on carrier substrate. In FIG. 7, the chip 20 is provided with the active surface 202 and the back surface 204, and a plurality of pads (not shown) is disposed on the active surface 202 and a plurality of connecting elements 22 is disposed thereon. Next, the active surface 202 of the chip 20 is flipped and is bonded on the circuit arrangement (not shown) on the top surface 502 of the carrier substrate 50, and the connecting elements 22 on the active surface 202 of the chip 20 is electrically connected with the circuit arrangement on the top surface 502 of the carrier substrate 50. Herein, it is noted that the plurality of through holes 510 is first formed near the center of the carrier substrate 50, the arrangement of the plurality of connecting elements 22 can be designed to dispose on the periphery of the active surface 202 of the chip 20, such that the plurality of connecting elements 22 would not be disposed or covered on the plurality of though holes 501, and the reliability of the semiconductor device would not be affected.

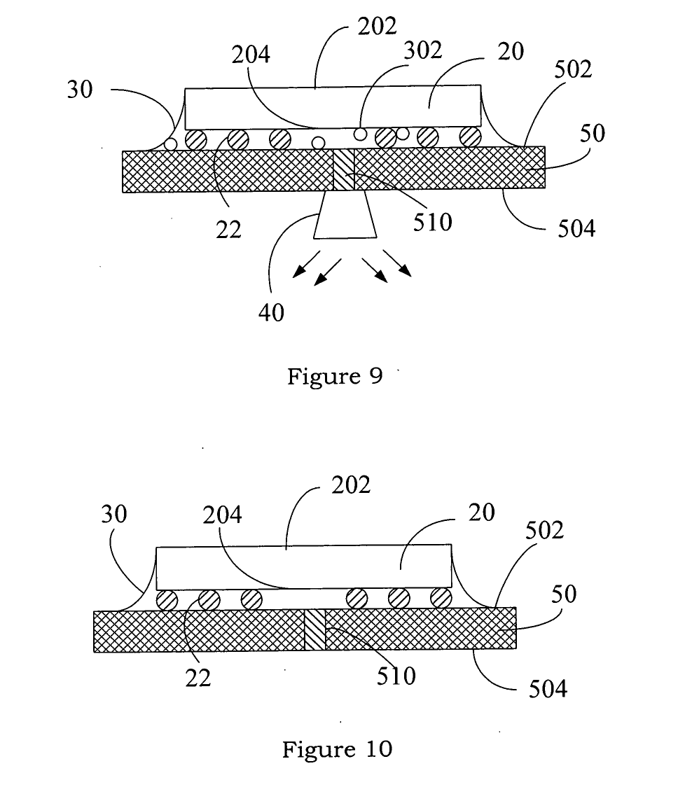

Then, please refer to FIG. 8, the underfilling material 30 is filled between the flip chip 20 and the carrier substrate 50, and filled with the through holes 510 within the carrier substrate 50 to accompany the flip-chip package process. Similarly, in the embodiment, the underfilling material 30 can increase the mechanical connection between the flip chip 20 and the carrier substrate 50, and can disperse the shearing stress between the connecting elements 22, such as solder ball, and chip 20. The underfilling material 30 may be polymeric material, such as epoxy resin or acrylic resin. The coefficient of thermal expansion (CTE) of the underfilling material 30 between the flip chip 20 and the carrier substrate 50 can reduce the shearing stress between the flip chip 20 and the carrier substrate 50. Unfortunately, there are some voids 302 exist within the underfilling material 30 between the flip chip 20 and the top surface 502 of the carrier substrate 50. The reason for the generation of voids 302 is that the underfilling duration is increased to ensure the underfilling material 30 that is filled completely between the flip chip 20 and the top surface 502 of the carrier substrate 50. Therefore, some voids would be generated within the underfilling material 30 between the flip chip 20 and the top surface 502 of the carrier substrate 50 when the underfilling material 30 accompanies some air to fill into. Unfortunately, these voids 302 will reduce the reliability of the semiconductor device. Therefore, in order to improve the reliability of the semiconductor device, the suction apparatus 40 is disposed under the through hole 510 within the back surface 504 of the carrier substrate 50 as shown in FIG. 9. The suction apparatus 40 is provided with a suction process to draw out the air within the underfilling material 30 to encapsulate completely between the flip chip 20 and the top surface 502 of the carrier substrate 50, and the underfilling material without having any voids 502 therein so as to the reliability and the yield of the semiconductor device can be increased, as shown in FIG. 10. In the embodiment, the suction apparatus 40 can be a vacuum pump.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A semiconductor device packaging method, comprising:
providing a carrier substrate having a top surface and a back surface, a circuit arrangement on said top surface and at least one through hole being disposed near a center portion of said carrier substrate and passed through said substrate;
providing a chip having an active surface and a back surface, a plurality of pads around a periphery of said active surface and a plurality of connecting elements on said plurality of pads;
attaching said chip on said top surface of said carrier substrate, said active surface of said chip being flipped and being bonded on said top surface of said carrier substrate and said plurality of connecting elements on said plurality of pads being electrically connected with said circuit arrangement, and said plurality of connecting elements being not covering on said at least one through hole;
filling a underfilling material to encapsulate between said plurality of connecting elements on said chip and said top surface of said carrier substrate, and said underfilling material being filled with said through hole; and
performing suction process to remove air between said plurality of connecting elements on said chip and said top surface of said carrier substrate, so that said underfilling material being filled between said plurality of connecting elements on said chip and said top surface of said carrier substrate.

2. The packaging method according to claim 1, wherein said carrier substrate comprises printed circuit board (PCB).

3. The packaging method according to claim 1, wherein said carrier substrate comprises flexible printed circuit board.

4. The packaging method according to claim 1, wherein the plurality of connecting elements comprises solder ball.

5. The packaging method according to claim 1, wherein the material of said underfilling material comprises polymer.

6. The packaging method according to claim 1, wherein the material of said underfilling material comprises epoxy resin.

7. The packaging method according to claim 1, wherein performing said suction process being provided with a vacuum pump which being disposed under said through hole on said back surface of said carrier substrate.

8. A semiconductor package device, comprising:
a carrier substrate having a top surface and a back surface, a circuit arrangement on said top surface and at least one through hole being disposed on a center portion of said carrier substrate and being passed through said carrier substrate;
a chip having an active surface and a back surface, a plurality of pads on the periphery of said active surface and a plurality of connecting elements on said plurality of pads, said active surface of said chip being flipped and being bonded on said top surface of said carrier substrate, and said plurality of connecting elements on said plurality of pads being electrically connected with said circuit arrangement on said top surface of said carrier substrate, and said plurality of connecting elements being not covering said at least one through hole; and
a underfilling material being filled to encapsulate between said plurality of connecting elements on said chip and said top surface of said carrier substrate, and said underfilling material being filled with said through hole.

9. The package device according to claim 8, wherein said carrier substrate comprises printed circuit board (PCB).

10. The package device according to claim 8, wherein said carrier substrate comprises flexible printed circuit board.

11. The package device according to claim 8, wherein said plurality of connecting elements comprises solder ball.

12. The package device according to claim 8, wherein said material of said underfilling material comprises polymer.

13. The package device according to claim 8, wherein said material of said underfilling material comprises epoxy resin.

14. A semiconductor package device, comprising:
a carrier substrate having a top surface and a back surface, a circuit arrangement on said top surface, and a plurality of through holes being disposed in a center of said carrier substrate and being formed passed through said carrier substrate;
a chip having an active surface and a back surface, a plurality of pads on a periphery of said active surface and a plurality of connecting elements on said plurality of pads, said active surface of said chip being flipped and being bonded on said top surface of said carrier substrate, and said plurality of connecting elements on said active surface of said chip being electrically connected with said circuit arrangement on said top surface of said carrier substrate, and said plurality of connecting elements being not covering said plurality of through holes; and
a underfilling material being filled to encapsulate between said plurality of connecting elements on said chip and said top surface of said carrier substrate, and being filled with said plurality of through holes.

15. The package device according to claim 14, wherein said plurality of through holes is disposed near a center of said carrier substrate.

16. The package device according to claim 14, wherein a position of said plurality of said through holes is not contacted with said plurality of connecting elements within said carrier substrate.

17. The package device according to claim 14, wherein said carrier substrate comprises printed circuit board (PCB).

18. The package device according to claim 14, wherein said carrier substrate comprises flexible printed circuit board.

19. The package device according to claim 14, wherein said plurality of connecting elements comprises solder ball.

20. The package device according to claim 14, wherein the material of said underfilling material is selected from the group consisting of polymer and epoxy resin.
